(19) United States
(12) Patent Application Publication
(10) Pub. No.: US 2026/0223499 A1
(43) Pub. Date: Jul. 30, 2026

(54) COVER STRUCTURES WITH CUTOUTS AWAY FROM EDGES FOR WIREBONDING

(71) Applicant: CreeLED, Inc., Durham, NC (US)

(72) Inventors: Andre Pertuit, Raleigh, NC (US); Sarah Trinkle, Creedmoor, NC (US); Colin Blakely, Raleigh, NC (US)

(21) Appl. No.: 19/037,694

(22) Filed: Jan. 27, 2025

(51) Int. Cl. H10H 20/857; H10H 20/01; H10H 20/831; H10H 20/85; H10H 20/851; H10H 20/855

(52) U.S. Cl. CPC H10H 20/857; H10H 20/0361; H10H 20/0363; H10H 20/0364; H10H 20/831; H10H 20/8502; H10H 20/8504; H10H 20/8514; H10H 20/855

(57) ABSTRACT

Light-emitting diode (LED) components and, more particularly, cover structures for LED components are disclosed. The cover structures have cut-outs for bond pads that are away from the edges of the cover structure and methods for fabricating the cover structures for the LED components. The cut-outs in the cover structure are enclosed by the non-cut-out portions of the cover structure i.e., the cut-out portions do not form an outer edge of the cover structure. This can maximize the coverage of the cover structure over the LED chip as well as make it easier to handle the cover structure. Additionally, cut-out portions can be formed in the cover structure prior to attaching and/or mounting the cover structure to the LED package, thus simplifying the fabrication process and avoiding the time consuming and wasteful exercise of grinding the cover structure to expose the bond pad after the LED chip is bump bonded.

### FIELD OF THE DISCLOSURE

The present disclosure relates to light-emitting diode (LED) components with cover structures that have cut-outs for bond pads that are away from the edges of the cover structure, and methods for fabricating the same.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode components, and more particularly, to cover structures for LED components that have cut-outs for bond pads that are away from the edges of the cover structure and methods for fabricating the cover structures for the LED components. The cut-outs in the cover structure are enclosed by the non-cut-out portions of the cover structure i.e., the cut-out portions do not form an outer edge of the cover structure. This can maximize the coverage of the cover structure over the LED chip as well as make it easier to handle the cover structure. Additionally, the cut-out portions can be formed in the cover structure prior to attaching and/or mounting the cover structure to the LED package, thus simplifying the fabrication process, and avoiding the time consuming and wasteful exercise of grinding the cover structure to expose the bond pad after the LED chip is bump bonded.

In one aspect, an LED package includes a submount, at least one LED chip on the submount, and a cover structure on the at least one LED chip, the cover structure comprising a cut-out portion that corresponds to a contact on the LED chip, wherein the contact is on a side of the LED chip facing the cover structure and wherein an edge of the cover structure encloses the cut-out portion. In an embodiment, the cover structure comprises a plurality of cut-out portions. In an embodiment, the cut-out portion is at least one of circular, oval, or rectangular. In an embodiment, the cover structure comprises a lumiphoric material. In an embodiment, the cover structure is formed from a phosphor sheet. In an embodiment, the cut-out portion is formed via a punch. In an embodiment, the cut-out portion is formed via a mold. In an embodiment, the cover structure is formed from at least one of phosphor in glass (PiG), glass, or sapphire. In an embodiment, the cut-out portion is formed via machining. In an embodiment, the cover structure is a lens.

In another aspect, a method for forming an LED package includes forming a cover structure comprising a cut-out portion, wherein an edge of the cover structure encloses the cut-out portion and placing the cover structure over an LED chip mounted on a submount, wherein the cut-out portion corresponds to a contact on the LED chip, wherein the contact is on a side of the LED chip facing the cover structure. In an embodiment, the method includes forming the cut-out portion via a punch. In an embodiment, the method includes forming the cut-out portion via a mold. In an embodiment, the method includes singulating a plurality of cover structures from a phosphor sheet, wherein each cover structure of the plurality of cover structures comprises at least one cut-out portion. In an embodiment, the singulating is performed by a same punch that forms the cut-out portion. In an embodiment, the cover structure is at least one of phosphor in glass (PiG), glass, or sapphire. In an embodiment, the method includes forming the cut-out portion via machining. In an embodiment, the cover structure comprises a lumiphoric material. In an embodiment, the cut-out portion is at least one of circular, oval, or rectangular.

In another aspect, a cover structure for an LED package includes a cut-out portion that corresponds to a contact on an LED chip of the LED package, wherein the contact is on a side of the LED chip facing the cover structure and wherein an edge of the cover structure encloses the cut-out portion, and wherein the cut-out portion is formed prior to placing the cover structure over the LED chip.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) package with a cover structure with a cut-out portion according to principles of the present disclosure.

FIG. 2 is a top-down view of a light-emitting diode (LED) package with a cover structure with a cut-out portion according to principles of the present disclosure.

FIG. 3 is a top-down view of another light-emitting diode (LED) package with a cover structure with two cut-out portions according to principles of the present disclosure.

FIG. 4 is a top-down view of a light-emitting diode (LED) package with a cover structure with an elongated cut-out portion according to principles of the present disclosure.

FIG. 5 is a top-down view of a light-emitting diode (LED) package with a cover structure with a circular cut-out portion according to principles of the present disclosure.

FIG. 6 is a top-down view of a light-emitting diode (LED) package with a lens cover structure with a cut-out portion according to principles of the present disclosure.

FIG. 7 is a sequence showing a punch forming a cut-out portion in a cover structure according to principles of the present disclosure.

FIG. 8 is an example of a punch that can form a cover structure with a cut-out portion of a cover structure from a phosphor sheet according to principles of the present disclosure.

FIG. 9 is a top-down view of a phosphor sheet with a plurality of cover structures with cut-out portions according to principles of the present disclosure.

FIG. 10 is a flow chart of a method for fabricating a cover structure with a cut-out portion according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode components, and more particularly, to cover structures for LED components that have cut-outs for bond pads that are away from the edges of the cover structure and methods for fabricating the cover structures for the LED components. The cut-outs in the cover structure are enclosed by the non-cut-out portions of the cover structure i.e., the cut-out portions do not form an outer edge of the cover structure. This can maximize the coverage of the cover structure over the LED chip as well as make it easier to handle the cover structure. Additionally, the cut-out portions can be formed in the cover structure prior to attaching and/or mounting the cover structure to the LED package, thus simplifying the fabrication process, and avoiding the time consuming and wasteful exercise of grinding the cover structure to expose the bond pad after the LED chip is bump bonded.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group Ill nitride-based material systems. Group Ill nitrides refer to semiconductor compounds formed between nitrogen (N) and elements in Group III of the periodic table, usually aluminum (AI), gallium (Ga), and/or indium (In) in the form of binary, ternary, and/or quaternary compounds. Other material systems include organic semiconductor materials, and other Group Ill-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

In certain embodiments, one or more lumiphoric materials may be provided as a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In certain embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures may also include ceramic phosphor plates, phosphor-in-glass structures, and/or single crystal phosphors. Support elements as used herein may also be referred to as superstrates to avoid confusion with substrates of LED chips.

Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may be thinned before or after the patterning process is performed. In certain embodiments, wavelength conversion elements and cover structures may comprise a generally planar upper surface that corresponds to a light emission area of the LED package. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements. Wavelength conversion elements and cover structures may be attached to one or more LED chips using, for example, a layer of transparent adhesive such as silicone.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a vertical geometry. A vertical geometry LED chip typically includes anode and cathode connections on opposing sides or faces of the LED chip. In an embodiment, there can be a bond pad for an electrode to connect to on a top of the chip opposite a side of the LED chip facing the submount.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure or a submount. Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern. Encapsulant materials may be formed to cover LED chips and portions of the submount and in certain embodiments, encapsulant materials may form lenses that direct light in desired emission directions and/or patterns.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

In conventional LED packages for vertical geometry chips, the cover structure is mounted to the LED package over the LED chip, and the cut-out portions for the bond pads are ground away to expose the bond pads, which can be wasteful and costly. Alternatively, the cut-out portions may be preformed but extend to the edge of the cover structure, and can thus be larger than necessary, and can complicate handling of the cover structure. Additionally, cut-out portions that extend to the edge of the cover structure may negatively affect the optical properties of the LED package by decreasing light extraction, or disrupting a desired emission pattern.

To solve these problems, the LED package with a cut-out portion that does not extend to an edge of the cover structure and is preformed, before attaching to the LED package is disclosed herein, which can make handling easier, as well as reduce the cost and waste of the fabrication process, and preserve or optimize the desired optical qualities of the LED package

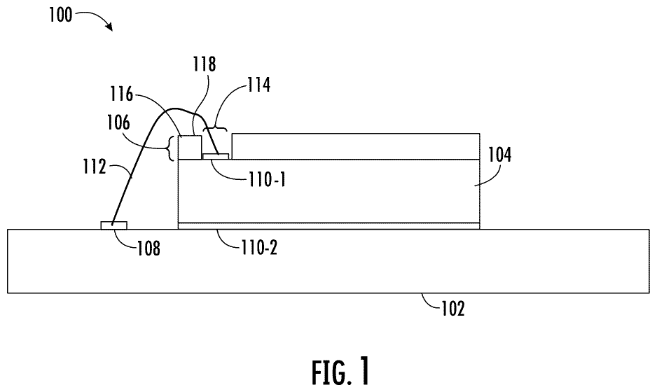

FIG. 1 is a cross-sectional view of a light-emitting diode (LED) package 100 with a cover structure 106 with a cut-out portion 114 according to principles of the present disclosure.

The cut-out portion 114 accommodates a vertical contact geometry for an LED chip 104 by providing access to bond pad 110-1, which is the electrode on a first side of the LED chip 104. The LED chip 104 includes another electrode 110-2 on the opposite side of the LED chip 104, the side which is also attached to the submount 102. The cover structure 106 includes the cut-out portion 114 to enable the wire bond 112 to make contact with the bond pad 110-1, and the wire bond 112 is also connected to trace 108 on the submount 102.

The cover structure 106 may be formed by any combination of one or more of a lumiphoric material, a support element or superstrate, an antireflective layer, a reflective layer, or a filter layer. In certain embodiments, any of the lumiphoric material, the superstrate, the antireflective layer, the reflective layer, and the filter layer may be omitted. In some embodiments, the cover structure 106 could be used for white conversion or could be an optical filter, or lens. In some embodiments, the cover structure 106 could be formed from a phosphor sheet, or could be glass, sapphire, or a PiG (phosphor in glass). For embodiments without wavelength conversion, the cover structure 106 may comprise a support element or superstrate, such as glass or sapphire, and may be devoid of lumiphoric materials.

Depending on the structure of the LED chip 104, the contact 110-1 may be configured as either the anode or the cathode for the LED chip 104 while the contact 110-2 may be configured as the other of the anode or the cathode.

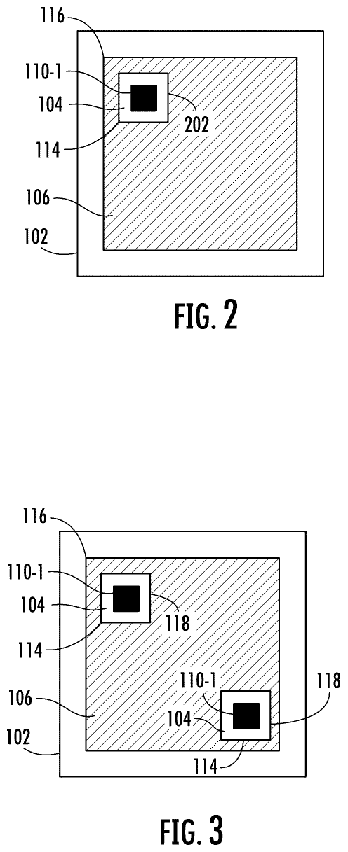

In an embodiment, the cut-out portion 114 can be within the cover structure 106—in other words, the cut-out portion 114 does not extend to a perimeter edge of the cover structure. This can be seen more clearly in FIG. 2. Another way of defining this is that an interior edge 118 of the cover structure 106 encircles or encloses the cut-out portion 114.

FIG. 2 is a top-down view of a light-emitting diode (LED) package with a cover structure with a cut-out portion according to principles of the present disclosure. The embodiment in FIG. 2 corresponds to the LED package 100 of FIG. 1, where the cut-out portion 114 is near the perimeter edge 116 of the cover structure 106, but does not extend to the perimeter edge 116. Instead, an edge or interior edge 118, of the cut-out portion 114 encloses the cut-out portion 114 entirely. The position of the cut-out portion 114 corresponds to the position of the bond pad 110-1 and enables the wire bond 112 to make contact with the bond pad 110-1 directly. In an embodiment, the wire bond 112 can make contact with a secondary bump bond that can be placed on the bond pad 110-1 before or after placement of the cover structure 106. In some embodiments, a portion of the LED chip 104 may be uncovered by the cut-out portion 114, but this can be minimized to increase the amount of light that passes through the cover structure 106.

In the embodiment shown in FIG. 2, the cut-out portion 114 can be near a corner of the cover structure 106, but in other embodiments, the cut-out portion 114 can be anywhere within the cover structure 106. Additionally, in the embodiment shown in FIG. 2, the cut-out portion 114 is square, but other shapes are possible too in other embodiments, including but not limited to: rectangular, circular, oval, etc.

FIG. 3 is a top-down view of another light-emitting diode (LED) package with a cover structure with two cut-out portions according to principles of the present disclosure.

In the embodiment shown in FIG. 3, there are two cut-out portions 114, but in other embodiments, there can be three or more. Additionally, while in the embodiment in FIG. 3, the cut-out portions 114 are in opposite corners. In other embodiments, they could be closer together, near the same corner, or in adjacent corners.

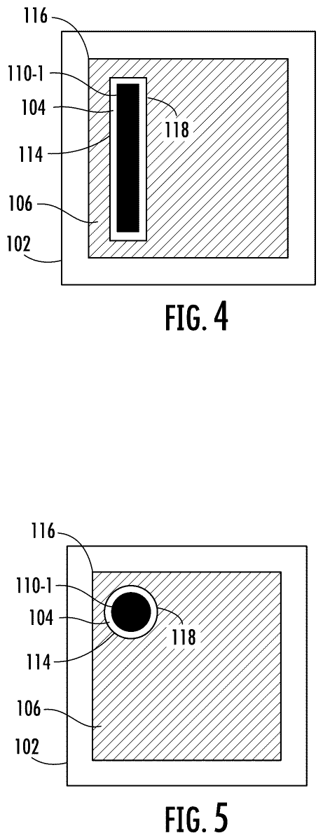

FIG. 4 is a top-down view of a light-emitting diode (LED) package with a cover structure 106 with an elongated cut-out portion 114 according to principles of the present disclosure. In an embodiment, the cut-out portion 114 need not be a quadrilateral but could be any size or shape. For example, the cut-out portion 114 could be sized and shaped to accommodate a secondary part of the LED package 100 such as an electrostatic discharge (ESD) diode.

FIG. 5 is a top-down view of a light-emitting diode (LED) package with a cover structure 106 with a circular cut-out portion 114 according to principles of the present disclosure. The circular shape of the cut-out portion 114 can be configured to correspond to a circular bond pad 110-1, and to minimize an amount of the LED 104 that is visible through the cut-out portion 114.

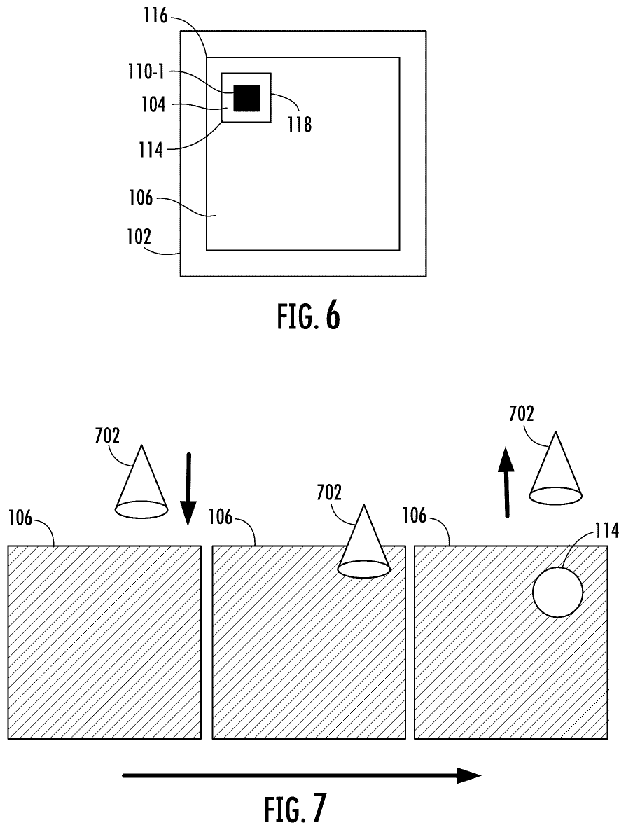

FIG. 6 is a top-down view of a light-emitting diode (LED) package with a cover structure with a cut-out portion according to principles of the present disclosure.

In the embodiment in FIG. 6, the cover structure 106 can be an optical filter or cover structure that is not related to wavelength conversion (e.g., no lumiphoric material).

FIG. 7 is a sequence showing a punch 702 forming a cut-out portion in a cover structure according to principles of the present disclosure.

The cover structure 106 with the cut-out portion 114 can be formed before the cover structure 106 is attached to the LED package 100 and/or placed over the LED chip 104, to avoid having to perform the wasteful and costly process of grinding away to expose the bond pad. To accomplish this, in one embodiment, as depicted in FIG. 7, a punch 702 can be used to punch out the cut-out portion 114. The punch 702 could be circular as depicted in FIG. 7, or could be any shape that is desired (e.g., square, rectangular, oval, etc.).

In an embodiment, the same punch 702 can punch out multiple cut-out portions 114 in the same cover structure 106 (e.g., to create a similar embodiment as that depicted in FIG. 3. Alternatively, multiple punches 702 could be used per cover structure 106.

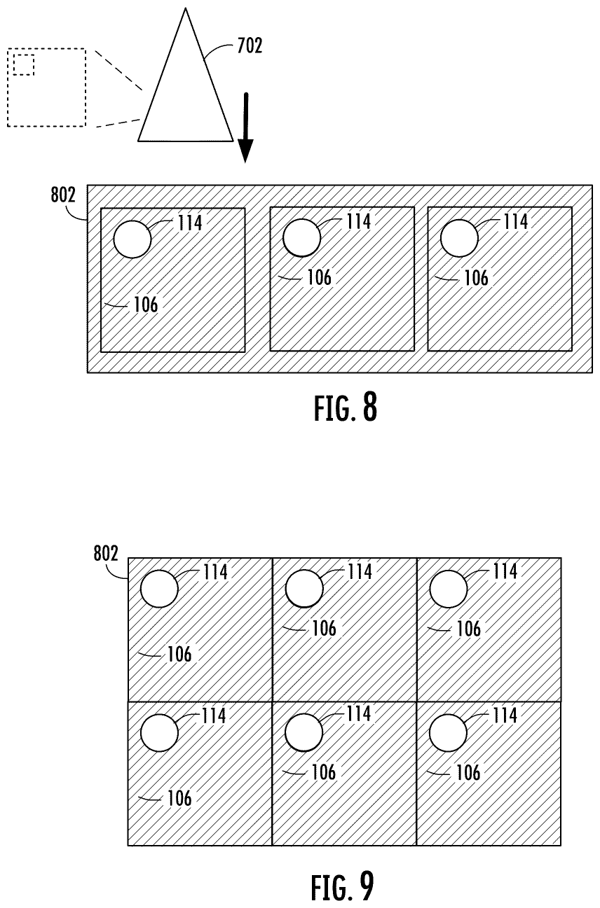

FIG. 8 is an example of a punch that can form a cover structure with a cut-out portion of a cover structure from a phosphor sheet according to principles of the present disclosure.

In the embodiment shown in FIG. 8, the punch 702 also includes the negative of the cover structure, and when punching into for example a sheet of phosphor 802, every punch results in a separate cover structure 106 with a respective one or more cut-out portions 114. The example in FIG. 8 shows a cover structure 106 with a single cut-out portion 114, but in other examples, the punch could create a cover structure 106 with two or more cut-out portions 114 per punch, or with different shaped cut-out portions 114.

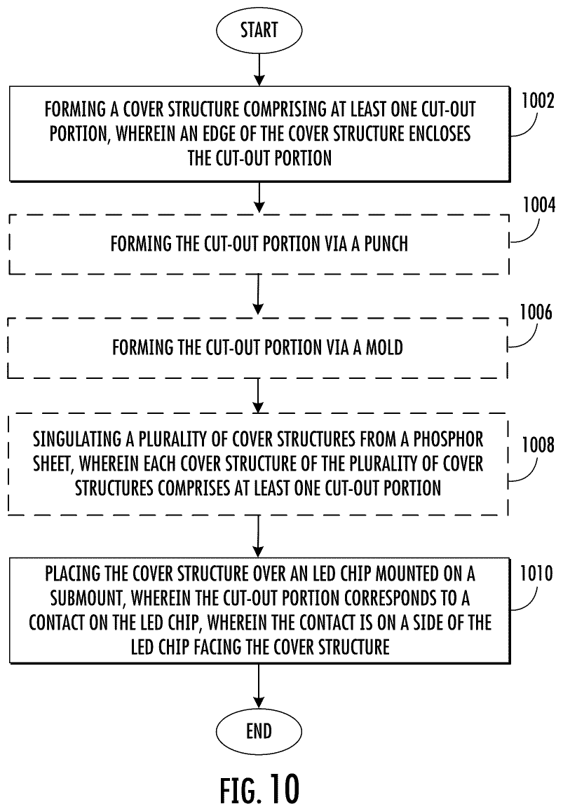

FIG. 9 is a top-down view of a phosphor sheet with a plurality of cover structures with cut-out portions according to principles of the present disclosure.

After forming multiple cover structures 106 from a sheet of phosphor 802 using either the punch 702 from FIG. 8 or the punch 702 from FIG. 7, the phosphor sheet 802 can be singulated to separate the cover structures 106 from each other for individual attachment in the LED packages 100. In an embodiment, the sheet of phosphor 802 with the multiple cover structure 106 still integral to the sheet of phosphor 802 can be attached to a plurality of aligned LED packages 100 and then singulated after attachment.

FIG. 10 is a flow chart of a method for fabricating a cover structure with a cut-out portion according to principles of the present disclosure.

At step 1002, the method includes forming a cover structure comprising at least one cut-out portion, wherein an edge of the cover structure encloses the cut-out portion. In an embodiment, the cover structure comprises a lumiphoric material, while in other embodiments, the cover structure does not include a lumiphoric material and does not perform white conversion and/or is just an optical filter.

At optional step 1004, the method includes forming the cut-out portion via a punch as similarly shown in FIGS. 7 and 8. Alternatively, at optional step 1006, the method may include forming the cut-out portion via a mold. This can be done when the cover structure is a phosphor sheet, and the cover structure is cast. The cut-out portion can be formed by a positive feature of the mold.

In other embodiments, when the cover structure is formed from a harder material such as PiG, glass, or sapphire, the cut-out portion can be machined using traditional micromachining methods.

In an embodiment where a phosphor sheet comprises a plurality of cover structures each with respective one or more cut-put portions (e.g., the embodiments in FIG. 8 or 9, the method may optionally include at step 1008 singulating a plurality of cover structures from a phosphor sheet, wherein each cover structure of the plurality of cover structures comprises at least one cut-out portion. In an embodiment, the singulating can be performed by the same punch that forms the cut-out portion, such as in FIG. 8.

At step 1010, the method includes placing the cover structure over an LED chip mounted on a submount, wherein the cut-out portion corresponds to a contact on the LED chip, wherein the contact is on a side of the LED chip facing the cover structure.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package, comprising:
a submount;
at least one LED chip on the submount; and
a cover structure on the at least one LED chip, the cover structure comprising a cut-out portion that corresponds to a contact on the LED chip, wherein the contact is on a side of the LED chip facing the cover structure and wherein an edge of the cover structure encloses the cut-out portion.

2. The LED package of claim 1, wherein the cover structure comprises a plurality of cut-out portions.

3. The LED package of claim 1, wherein the cut-out portion is at least one of circular, oval, or rectangular.

4. The LED package of claim 1, wherein the cover structure comprises a lumiphoric material.

5. The LED package of claim 1, wherein the cover structure is formed from a phosphor sheet.

6. The LED package of claim 5, wherein the cut-out portion is formed via a punch.

7. The LED package of claim 5, wherein the cut-out portion is formed via a mold.

8. The LED package of claim 1, wherein the cover structure is formed from at least one of phosphor in glass (PiG), glass, or sapphire.

9. The LED package of claim 8, wherein the cut-out portion is formed via machining.

10. The LED package of claim 1, wherein the cover structure is a lens.

11. A method for forming an LED package, comprising:
forming a cover structure comprising a cut-out portion, wherein an edge of the cover structure encloses the cut-out portion; and
placing the cover structure over an LED chip mounted on a submount, wherein the cut-out portion corresponds to a contact on the LED chip, wherein the contact is on a side of the LED chip facing the cover structure.

12. The method of claim 11, further comprising:
forming the cut-out portion via a punch.

13. The method of claim 11, further comprising:
forming the cut-out portion via a mold.

14. The method of claim 11, further comprising:
singulating a plurality of cover structures from a phosphor sheet, wherein each cover structure of the plurality of cover structures comprises at least one cut-out portion.

15. The method of claim 14, wherein the singulating is performed by a same punch that forms the cut-out portion.

16. The method of claim 11 wherein the cover structure is at least one of phosphor in glass (PiG), glass, or sapphire.

17. The method of claim 16, further comprising forming the cut-out portion via machining.

18. The method of claim 11, wherein the cover structure comprises a lumiphoric material.

19. The method of claim 11, wherein the cut-out portion is at least one of circular, oval, or rectangular.

20. A cover structure for a light-emitting diode (LED) package, the cover structure comprising:
a cut-out portion that corresponds to a contact on an LED chip of the LED package, wherein the contact is on a side of the LED chip facing the cover structure and wherein an edge of the cover structure encloses the cut-out portion, and wherein the cut-out portion is formed prior to placing the cover structure over the LED chip.
